(19) United States
(12) Patent Application Publication
(10) Pub. No.: US 2021/0270114 A1
(43) Pub. Date: Sep. 2, 2021

(54) Optimization method for high-efficiently placing proppants in hydraulic fracturing treatment

(71) Applicant: Southwest Petroleum University, Chengdu (CN)

(72) Inventors: Xiyu Chen, Chengdu (CN); Yongming Li, Chengdu (CN); Jinzhou Zhao, Chengdu (CN); Huibo Wen, Chengdu (CN); Bin Fu, Chengdu (CN); Zhibo Yu, Chengdu (CN)

(73) Assignee: Southwest Petroleum University

(21) Appl. No.: 17/324,125

(22) Filed: May 19, 2021

(30) Foreign Application Priority Data
Feb. 19, 2021 (CN) 202110191568.6

(51) Int. Cl. E21B 43/26

(52) U.S. Cl. CPC E21B 43/26; E21B 2200/20

(57) ABSTRACT

An optimization method for high-efficiently placing proppants in a hydraulic fracturing treatment includes steps of: (1) constructing a rock deformation governing equation during a fracturing process, and constructing a material balance equation of flowing of fracturing fluid and transport of the proppant; (2) constructing a model for representing a pumped volume fraction of the proppant; (3) calculating with given parameters, and obtaining corresponding fracture geometric size and volumetric concentration distribution of the proppant; (4) calculating a placement efficiency of the proppant for each set of parameters; (5) calculating an average placement efficiency of the proppant under different parameters; (6) selecting optimized parameters; (7) substituting the optimized parameters into the models constructed in the steps (1) and (2), calculating the placement efficiency of the proppant as step (4), and verifying whether the placement efficiency is maximum, which means the optimized parameters are optimal.

### CROSS REFERENCE OF RELATED APPLICATION

The application claims priority under 35 U.S.C. 119(a-d) to CN 202110191568.6, filed Feb. 19, 2021.

### BACKGROUND OF THE PRESENT INVENTION

### Field of Invention

The present invention relates to a technical field of oil & gas filed development, and more particularly to an optimization method for high-efficiently placing proppants in a hydraulic fracturing treatment.

### Description of Related Arts

For the low permeability oil & gas reservoir, the hydraulic fracturing technology is one of the most effective technologies for increasing the production. By pumping the high-pressure fluid carrying proppant particles into the oil & gas well, the hydraulic fracturing technology can create many hydraulic fractures with certain widths in the reservoir rocks, as the high-speed flowing channels for oil & gas, so that the production of these low permeability reservoirs can be improved. After completing the hydraulic fracturing treatment, the created hydraulic fractures will rapidly close under a high closure pressure in the underground. At this time, the fracture area which is not effectively filled by the proppant particles will be closed and its permeability will greatly decrease, leading to less contribution to the production. Thus, whether the proppant particles can be accurately placed in the required areas of the fractures is important to the final performance of the hydraulic fracturing treatment for increasing the production.

When the proppants are pumped into the fractures, the mutual frictions among these particles, the sliding between the particles and fracture surfaces, and the gravity of these particles all contribute to the difference of transport mechanisms between solid particles and fracturing fluid. Moreover, with a high concentration, the proppant particles may bridge and block at the narrow zone in the hydraulic fractures, thereby preventing flowing of the fracturing fluid into the zone and affecting the placement of the proppant particles. The above two physical mechanisms interact with each other, making it difficult for the engineers to forecast and control the transport and placement of the proppant particles in the hydraulic fractures and to optimize the design. It is predictable that an improper design for proppant injection will seriously harm the effectiveness of the hydraulic fracture treatment. On one hand, if the proppants are not effectively placed within the fractures of the pay zone, the production will be decreased; on the other hand, if a large number of proppants are inappropriately placed within the undesired zone, it will be a waste of construction cost.

In order to ensure the effective placement of the proppants in the hydraulic fracturing treatment, many researchers carry out the numerical simulations, lab experiments and field tests, so as to study the transport and settlement mechanisms of the proppant particles. Lab experiments make it possible to directly observe and study the phenomenon and mechanisms of proppant transport in the fractures. However, in such experiments, the fractures have fixed widths, which are different from the actual hydraulic fractures whose widths change dynamically with the pressure. In contrast, the analysis results obtained by the field tests with tracer agent are more valuable, but with too much cost. Also, these data sometimes can hardly locate the accurate transport of the proppant. Due to these difficulties, numerical simulation becomes the most common method for studying the transport and settlement mechanisms of the proppant in the hydraulic fracturing treatment, and with its low cost, it is widely used for optimizing the design of fracturing treatment. However, at present, most of the numerical optimization methods for proppant placement are not standardized, which are depending on the tedious parameter adjustment by engineer's experience and showing poor efficiency and effectiveness.

### SUMMARY OF THE PRESENT INVENTION

Aiming at existing problems in prior art, the present invention provides an optimization method for improving effectiveness of proppant placement in a hydraulic fracturing treatment, so as to place proppant particles of a predetermined total volume within an oil & gas pay zone as far as possible.

The present invention adopts technical solutions as follows.

An optimization method for high-efficiently placing proppants in a hydraulic fracturing treatment comprises steps of:

(1) constructing a rock deformation governing equation during a fracturing process; constructing a material balance equation of flowing of fracturing fluid and transport of the proppant; coupling the equations and constructing a fracture propagation model, for solving a geometric size of a hydraulic fracture and a volumetric concentration distribution of the proppant;

(2) constructing a model for representing a pumped volume fraction of the proppant;

(3) according to geological and engineering parameters of a target area, determining a total pumped volume of the proppant; determining d different initial times for pumping the proppant, d different numbers of slugs of the pumped proppant, and d different average diameters of proppant particles; according to a L_{d×d} table of orthogonal experimental design, obtaining d×d sets of parameters; substituting the d×d sets of parameters respectively into the models constructed in the steps (1) and (2), and obtaining corresponding fracture geometric size and volumetric concentration distribution of the proppant;

(4) according to the fracture geometric size and the volumetric concentration distribution of the proppant, which are obtained in the step (3), calculating a placement efficiency of the proppant for each set of parameters;

(5) according to the placement efficiency of the proppant, which is obtained in the step (4), respectively calculating an average placement efficiency T₁ under different initial times for pumping the proppant, an average placement efficiency Nᵢ under different numbers of the slugs of the pumped proppant, and an average placement efficiency Aᵢ under different average diameters of the proppant particles, 1=1, 2, . . . , d;

(6) according to results obtained in the step (5), respectively selecting a maximum value among Tᵢ, Nᵢ and Aᵢ; according to the maximum value, selecting the corresponding initial time for pumping the proppant, number of the slugs of the pumped proppant and average diameter of the proppant particles, as optimized parameters;

(7) substituting the optimized parameters obtained in the step (6) into the models constructed in the steps (1) and (2), and obtaining the corresponding fracture geometric size and volumetric concentration distribution of the proppant; calculating the placement efficiency of the proppant as step (4), and verifying whether the placement efficiency is maximum, which means the optimized parameters obtained in the step (6) are optimal.

Preferably, the rock deformation governing equation during the fracturing process in the step (1) is:

p(x′,y′)=σ(y′)+∫ₛC(x′−x,y′−y)w(x,y)dxdy;

in the equation, x and y are space coordinates; p is a net pressure value in the fracture; a is a value of a minimum principal stress of formation; w is a width of the hydraulic fracture; C is a kernel function; and S is a fracture area; wherein:

the kernel function C is:

$$C ( x , y ) = - \frac{E}{8 π ( 1 - {v}^{2} )} \frac{1}{{( {x}^{2} + {y}^{2} )}^{3 / 2}} ;$$

in the equation, v is a Poisson's ratio of reservoir rocks, and E is a Young's modulus of the reservoir rocks;

the material balance equation of flowing of the fracturing fluid and transport of the proppant is:

$$\{ \begin{matrix}\frac{\partial w}{\partial t} + ∇ \cdot {q}_{s} = {Q}_{0} δ ( x , y ) \\ \frac{\partial w φ}{\partial t} + ∇ \cdot {q}_{p} = {Q}_{0} {φ}_{in} δ ( x , y )\end{matrix} ;$$

in the equation, qₛ is a flowing rate of the fracturing fluid; qₚ is a transport rate of the proppant; Q₀ is a pumped volume of the fracturing fluid; φᵢₙ is the pumped volume fraction of the proppant; φ is a volume fraction of the proppant in the fracture; and t is time; wherein:

$$\{ \begin{matrix}{q}_{s} = \frac{{w}^{3}}{12 μ} {Q}_{s} ( φ ) ∇ p \\ {q}_{p} = B ( φ ) ( {Q}_{p} ( φ ) {q}_{s} - \frac{{a}^{2} w}{12 μ} {gG}_{p} ( φ ) )\end{matrix} ;$$

in the equation, Qₛ is a dimensionless equation representing rheology of the fracturing fluid; μ is a viscosity of the fracturing fluid; B is a blocking equation of the proppant; Qₚ is a dimensionless equation representing a transport mechanism of the proppant; a is the average diameter of the proppant particles; g is a gravitational acceleration; and Gₚ is a dimensionless equation representing a settlement mechanism of the proppant;

$$\{ \begin{matrix}{Q}_{s} ( φ ) = {( 1 - φ )}^{2} \\ {Q}_{p} ( φ ) = 1.2 {φ ( 1 - φ )}^{0.1} \\ {G}_{p} ( φ ) = 2.3 {φ ( 1 - φ )}^{2}\end{matrix} ; \\ B ( φ ) = H ( \frac{w}{a} - 4 ) + ( \frac{w}{a} - 3 ) H ( 4 - \frac{w}{a} ) H ( \frac{w}{a} - 3 ) ;$$

in the equation, H is a unit step function;

a boundary condition of a fracture tip is:

$${lim}_{r -> 0} w = \sqrt{\frac{32}{π}} \frac{{K}_{IC} ( 1 - {v}^{2} )}{E} {r}^{1 / 2} ;$$

in the equation, K_{IC} is a fracture toughness, and r is a distance away from the fracture tip.

Preferably, the model constructed in the step (2) is:

$$\{ \begin{matrix}Δ {t}_{p} = ( T - {t}_{c} ) / n \\ Δ φ = 2 Φ / [ ( n + 1 ) ( T - {t}_{c} ) ] \\ {φ}_{in} = ⌊ ( t - {t}_{c} ) / Δ {t}_{p} + 1 ⌋ Δφ / {Q}_{0} / 0.64\end{matrix} ;$$

in the equation, Δtₚ is a duration time of each slug of the proppant; T is a total time for injecting the fracturing fluid; t_{c} is the initial time for pumping the proppant; n is the number of the slugs of the pumped proppant; Δφ is an increment of the volume fraction of the proppant between two neighboring slugs; Φ is the total pumped volume of the proppant; φᵢₙ is the pumped volume fraction of the proppant; t is time; and Q₀ is the pumped volume of the fracturing fluid.

Preferably, the placement efficiency yᵢ of the proppant in the step (4) is calculated as follows:

$${y}_{i} = \frac{{Φ}_{eff}}{Φ} \frac{{S}_{eff}}{{S}_{teff}} , \\ i = 1 , 2 , 3 … m ;$$

in the equation, Φ_{eff} is a volume of the proppant placed in an oil & gas pay zone after fracturing; S_{eff} is an area of the proppant placed in the oil & gas pay zone after fracturing; S_{teff} is a total area of the oil & gas pay zone covered by the hydraulic fracture after fracturing; Φ is the total pumped volume of the proppant; m is an amount of parameter sets and equals to d×d.

Preferably, the optimization method further comprises steps of: comparing the placement efficiency of the proppant, which is obtained in the step (7), with the placement efficiencies of m sets which are obtained in the step (4), wherein: if the placement efficiency obtained in the step (7) is maximum, the optimized parameters obtained in the step (6) are considered as optimal results.

The present invention has beneficial effects as follows.

First, the optimized parameters obtained through the method provided by the present invention can increase both the ratios of volume and cover area of the proppant placed in the pay zone, which are more reliable.

Second, according to the present invention, the initial time for pumping the proppant, the number of the slugs of the pumped proppant and the average diameter of the proppant particles are adopted to represent the design for pumping the proppant. With the orthogonal analyses, the optimization method has objectivity and practicability.

Third, the present invention presents a fracturing numerical model, which is fully fluid-solid coupled with considering the transport of the proppants, and the fracturing model is able to quantitatively evaluate the concentration distribution of the proppant in the hydraulic fracture. By utilizing the presented model, the optimized result of the present invention has objectivity with eliminating the interference of the subjective evaluation.

### BRIEF DESCRIPTION OF THE DRAWINGS

FIG. 1 shows a numerical simulation result of optimized fracture geometric size and proppant distribution of a 4^{th} section of a tight gas well TL according to a preferred embodiment 1;

FIG. 2 shows an optimized design for proppant injection of the 4^{th} section of the tight gas well TL according to the preferred embodiment 1;

FIG. 3 shows a numerical simulation result of optimized fracture geometric size and proppant distribution of a 1^{st} section of a tight oil well X2 according to a preferred embodiment 2;

FIG. 4 shows an optimized design for proppant injection of the 1^{st} section of the tight oil well X2 according to the preferred embodiment 2.

### DETAILED DESCRIPTION OF THE PREFERRED EMBODIMENT

The present invention will be further illustrated with the accompanying drawings and the preferred embodiments.

An optimization method for high-efficiently placing proppants in a hydraulic fracturing treatment comprises steps of:

(1) constructing a rock deformation governing equation during a fracturing process; constructing a material balance equation of flowing of fracturing fluid and transport of the proppant; coupling the equations and constructing a fracture propagation model, for solving a geometric size of a hydraulic fracture and a volumetric concentration distribution of the proppant; wherein:

the rock deformation governing equation during the fracturing process in the step (1) is:

p(x′,y′)=σ(y′)+∫ₛC(x′−x,y′−y)w(x,y)dxdy;

in the equation, x and y are space coordinates, in unit of m; p is a net pressure value in the fracture, in unit of MPa; σ is a value of a minimum principal stress of formation, in unit of MPa; w is a width of the hydraulic fracture, in unit of m; C is a kernel function; and S is a fracture area; wherein:

the kernel function C is:

$$C ( x , y ) = - \frac{E}{8 π ( 1 - {ν}^{2} )} \frac{1}{{( {x}^{2} + {y}^{2} )}^{3 / 2}} ;$$

in the equation, v is a Poisson's ratio of reservoir rocks, and E is a Young's modulus of the reservoir rocks;

the material balance equation of flowing of the fracturing fluid and transport of the proppant is:

$$\{ \begin{matrix}\frac{\partial w}{\partial t} + ∇ \cdot {q}_{s} = {Q}_{0} δ ( x , y ) \\ \frac{\partial w φ}{\partial t} + ∇ \cdot {q}_{p} = {Q}_{0} {φ}_{in} δ ( x , y )\end{matrix} ;$$

in the equation, qₛ is a flowing rate of the fracturing fluid, in unit of m²/s; qₚ is a transport rate of the proppant, in unit of m²/s; Q₀ is a pumped volume of the fracturing fluid, in unit of m³/s; φᵢₙ is a pumped volume fraction of the proppant; φ is a volume fraction of the proppant in the fracture; and t is time; wherein:

$$\{ \begin{matrix}{q}_{s} = \frac{{w}^{3}}{12 μ} {Q}_{s} ( φ ) ∇ p \\ {q}_{p} = B ( φ ) ( {Q}_{p} ( φ ) {q}_{s} - \frac{{a}^{2} w}{12 μ} {gG}_{p} ( φ ) )\end{matrix} ;$$

in the equation, Qₛ is a dimensionless equation representing rheology of the fracturing fluid; μ is a viscosity of the fracturing fluid, in unit of MPa·s; B is a blocking equation of the proppant; Qₚ is a dimensionless equation representing a transport mechanism of the proppant; a is an average diameter of proppant particles, in unit of m; g is a gravitational acceleration; and Gₚ is a dimensionless equation representing a settlement mechanism of the proppant;

$$\{ \begin{matrix}{Q}_{s} ( φ ) = {( 1 - φ )}^{2} \\ {Q}_{p} ( φ ) = 1.2 {φ ( 1 - φ )}^{0.1} \\ {G}_{p} ( φ ) = 2.3 {φ ( 1 - φ )}^{2}\end{matrix} ; \\ B ( φ ) = H ( \frac{w}{a} - 4 ) + ( \frac{w}{a} - 3 ) H ( 4 - \frac{w}{a} ) H ( \frac{w}{a} - 3 ) ;$$

in the equation, H is a unit step function;

a boundary condition of a fracture tip is:

$${lim}_{r \to 0} w = \sqrt{\frac{32}{π}} \frac{{K}_{1 C} ( 1 - {ν}^{2} )}{E} {r}^{1 / 2} ;$$

in the equation, K_{IC} is a fracture toughness, in unit of MPa·s^{0.5}; and r is a distance away from the fracture tip, in unit of m;

(2) constructing a model for representing the pumped volume fraction of the proppant; wherein:

in the model, the average diameter a of the proppant particles and the pumped volume fraction φᵢₙ of the proppant which changes in real time (namely a proppant injection program) belong to unknown optimized parameters; in the actual fracturing treatment, the pumped proppant is generally divided into multiple slugs, and displacements thereof are increased stepwise;

for the above mechanism, the mathematical model for representing the pumped volume fraction φᵢₙ of the proppant is constructed as follows:

$$\{ \begin{matrix}Δ {t}_{p} = ( T - {t}_{c} ) / n \\ Δφ = 2 Φ / [ ( n + 1 ) ( T - {t}_{c} ) ] \\ {φ}_{in} = ⌊ ( t - {t}_{c} ) / {Δt}_{p} + 1 ⌋ Δφ / {Q}_{0} / 0.64\end{matrix} ;$$

under a given total pumped volume of the proppant, required unknown parameters for calculating a dynamic change of the pumped volume fraction φᵢₙ are an initial time t_{c} for pumping the proppant and a number n of slugs of the pumped proppant;

Δtₚ is a duration time of each slug of the proppant, in unit of s; T is a total time for injecting the fracturing fluid, in unit of s; t_{c} is the initial time for pumping the proppant, in unit of s; n is the number of the slugs of the pumped proppant; Δφ is an increment of the volume fraction of the proppant between two neighboring slugs, in unit of m³; Φ is the total pumped volume of the proppant, in unit of m³; φᵢₙ is the pumped volume fraction of the proppant; t is time; and Q₀ is the pumped volume of the fracturing fluid, in unit of m³/s;

(3) according to geological and engineering parameters of a target area, determining the total pumped volume of the proppant; determining d different initial times for pumping the proppant, d different numbers of the slugs of the pumped proppant, and d different average diameters of the proppant particles; according to a L_{d×d} table of orthogonal experimental design, obtaining d×d sets of parameters; substituting the d×d sets of parameters respectively into the models constructed in the steps (1) and (2), and obtaining corresponding fracture geometric size and volumetric concentration distribution of the proppant; wherein:

in the present invention, d=4, and 16 sets of parameters need to be set; based on the initial time t_{c} for pumping the proppant, the number n of the slugs of the pumped proppant and the average diameter a of the proppant particles, which are listed in Table 1, the fracture geometric size and the volumetric concentration distribution of the proppant for 16 sets of parameters are respectively calculated;

TABLE 1
L₁₆ table of orthogonal experimental design, for
optimizing placement efficiency of proppant

| | | Number n of | Average diameter |
|---|---|---|---|
| Simulation | Initial time t_{c} | slugs of | a of proppant |
| number | for pumping proppant | pumped proppant | particles |
| 1 | 0.2 × T | 6 | 5 × 10⁻⁴ m |
| 2 | 0.4 × T | 12 | 1 × 10⁻⁴ m |
| 3 | 0.3 × T | 12 | 5 × 10⁻⁴ m |
| 4 | 0.5 × T | 6 | 1 × 10⁻⁴ m |
| 5 | 0.2 × T | 9 | 1 × 10⁻⁴ m |
| 6 | 0.4 × T | 3 | 5 × 10⁻⁴ m |
| 7 | 0.3 × T | 3 | 1 × 10⁻⁴ m |
| 8 | 0.5 × T | 9 | 5 × 10⁻⁴ m |
| 9 | 0.2 × T | 3 | 8 × 10⁻⁴ m |
| 10 | 0.4 × T | 9 | 3 × 10⁻⁴ m |
| 11 | 0.3 × T | 9 | 8 × 10⁻⁴ m |
| 12 | 0.5 × T | 3 | 3 × 10⁻⁴ m |
| 13 | 0.2 × T | 12 | 3 × 10⁻⁴ m |
| 14 | 0.4 × T | 6 | 8 × 10⁻⁴ m |
| 15 | 0.3 × T | 6 | 3 × 10⁻⁴ m |
| 16 | 0.5 × T | 12 | 8 × 10⁻⁴ m |

(4) according to the fracture geometric size and the volumetric concentration distribution of the proppant, which are obtained in the step (3), calculating a placement efficiency of the proppant for each set of parameters; wherein:

the placement efficiency yᵢ of the proppant is calculated as follows:

$${y}_{i} = \frac{{Φ}_{eff}}{Φ} \frac{{S}_{eff}}{{S}_{teff}} , i = 1 , 2 , 3 … m ;$$

in the equation, Φ_{eff} is a volume of the proppant placed in an oil & gas pay zone after fracturing, in unit of m³; S_{eff} is an area of the proppant placed in the oil & gas pay zone after fracturing, in unit of m²; S_{teff} is a total area of the oil & gas pay zone covered by the hydraulic fracture after fracturing, in unit of m²; Φ is the total pumped volume of the proppant, in unit of m³; m is an amount of parameter sets and is 16 in the present invention;

(5) according to the placement efficiency of the proppant, which is obtained in the step (4), respectively calculating an average placement efficiency T₁ under different initial times for pumping the proppant, an average placement efficiency Nᵢ under different numbers of the slugs of the pumped proppant, and an average placement efficiency Aᵢ under different average diameters of the proppant particles, 1=1, 2, . . . , d; wherein:

if adopting the parameters listed in the L₁₆ table in the step (3), according to the placement efficiency yᵢ of the proppant after hydraulic fracturing for 16 sets of parameters, calculated in the step (4), the average placement efficiency Tᵢ under different initial times for pumping the proppant, the average placement efficiency Nᵢ under different numbers of the slugs of the pumped proppant, and the average placement efficiency Aᵢ under different average diameters of the proppant particles are respectively calculated as follows:

$$\{ \begin{matrix}{T}_{1} = ( {y}_{1} + {y}_{5} + {y}_{9} + {y}_{13} ) / 4 \\ {T}_{2} = ( {y}_{3} + {y}_{7} + {y}_{11} + {y}_{15} ) / 4 \\ {T}_{3} = ( {y}_{2} + {y}_{6} + {y}_{10} + {y}_{14} ) / 4 \\ {T}_{4} = ( {y}_{4} + {y}_{8} + {y}_{12} + {y}_{16} ) / 4\end{matrix} ; \\ \{ \begin{matrix}{N}_{1} = ( {y}_{6} + {y}_{7} + {y}_{9} + {y}_{12} ) / 4 \\ {N}_{2} = ( {y}_{1} + {y}_{4} + {y}_{14} + {y}_{15} ) / 4 \\ {N}_{3} = ( {y}_{5} + {y}_{8} + {y}_{10} + {y}_{11} ) / 4 \\ {N}_{4} = ( {y}_{2} + {y}_{3} + {y}_{13} + {y}_{16} ) / 4\end{matrix} ; \\ \{ \begin{matrix}{A}_{1} = ( {y}_{2} + {y}_{4} + {y}_{5} + {y}_{7} ) / 4 \\ {A}_{2} = ( {y}_{10} + {y}_{12} + {y}_{13} + {y}_{15} ) / 4 \\ {A}_{3} = ( {y}_{1} + {y}_{3} + {y}_{6} + {y}_{8} ) / 4 \\ {A}_{4} = ( {y}_{9} + {y}_{11} + {y}_{14} + {y}_{16} ) / 4\end{matrix} ;$$

(6) according to results obtained in the step (5), respectively selecting a maximum value among Tᵢ, Nᵢ and Aᵢ; according to the maximum value, selecting the corresponding initial time for pumping the proppant, number of the slugs of the pumped proppant and average diameter of the proppant particles; wherein:

in the present invention, after selecting the maximum value among Tᵢ, Nᵢ and Aᵢ, according to the number corresponding to the maximum value and Table 2, the optimized initial time t_{c} for pumping the proppant, number n of the slugs and average diameter a of the proppant particles are selected as optimized parameters;

TABLE 2
Optimized parameter table

| | | | | | Average diameter |
|---|---|---|---|---|---|
| | Initial time t_{c} | | Number n of slugs of | | a of proppant |
| Number | for pumping proppant | Number | pumped proppant | Number | particles |
| T₁ | 0.2 × T | N₁ | 3 | A₁ | 1 × 10⁻⁴ m |
| T₂ | 0.3 × T | N₂ | 6 | A₂ | 3 × 10⁻⁴ m |
| T₃ | 0.4 × T | N₃ | 9 | A₃ | 5 × 10⁻⁴ m |
| T₄ | 0.5 × T | N₄ | 12 | A₄ | 8 × 10⁻⁴ m |

(7) substituting the optimized parameters (the initial time t_{c} for pumping the proppant, the number n of the slugs of the pumped proppant, and the average diameter a of the proppant particles) obtained in the step (6) into the models constructed in the steps (1) and (2), and obtaining the corresponding fracture geometric size and volumetric concentration distribution of the proppant; calculating the placement efficiency yᵢ of the proppant as step (4), and verifying whether the placement efficiency is maximum, which means the optimized parameters obtained in the step (6) are optimal.

Through comparing with the results of other sets, whether the design for proppant injection is optimal (the highest placement efficiency of the proppant) is determined. Through multiplying the optimized pumped volume fraction φᵢₙ of the proppant by 0.64, the sand ratio for proppant injection is obtained, which can be directly applied in guiding the engineering design.

### Preferred Embodiment 1

The 4^{th} section of the tight gas well TL in Sichuan is taken as an example, for further illustrating the method provided by the present invention.

According to the mathematical models constructed in the steps (1) and (2), the geometric size of the hydraulic fracture and the volumetric concentration distribution of the proppant after hydraulic fracturing are predicted. Based on the above models, according to the equation in the step (2), the pumped volume fraction φᵢₙ of the proppant is represented.

The geological and engineering parameters of the 4^{th} section of the tight gas well TL are collected and listed in Table 3.

TABLE 3
Geological and engineering parameter table of 4^{th} section of tight gas well TL

| | | | |
|---|---|---|---|
| Young's modulus (E, in unit of MPa) | 27000 | Poisson's ratio (v) | 0.22 |
| Stress difference between pay zone | 1.5 | Thickness of pay zone (h, in unit | 30 |
| and interlayer (Δσ, in unit of MPa) | | of m) | |
| Fracturing fluid viscosity (μ, in unit of | 1 × 10⁻⁸ | Total pumped volume of | 0.025 |
| MPa · s) | | fracturing fluid (Qₒ, in unit of | |
| | | m³/s) | |
| Fracturing fluid density (ρ_{f}, in unit of | 1000 | Proppant density (ρₚ, in unit of | 2600 |
| kg/m³) | | kg/m³) | |
| Fracture toughness (K_{IC}, in unit of | 1.6 | Total time for injecting fracturing | 2400 |
| MPa · s^{0.5}) | | fluid (T, in unit of s) | |

Based on the 16 sets of initial time t_{c} for pumping the proppant, number n of the slugs of the pumped proppant, and average diameter a of the proppant particles, listed in Table 1, 16 sets of fracture geometric size and volumetric concentration distribution of the proppant are respectively calculated.

According to the obtained fracture geometric size and volumetric concentration distribution of the proppant, the placement efficiency of the proppant for 16 sets of parameters are respectively calculated through the equation in the step (4) and results thereof are listed in Table 4.

TABLE 4
Placement efficiency of proppant for 16 sets
of parameters in preferred embodiment 1

| Simulation number | $\frac{{Φ}_{eff}}{Φ}$ | $\frac{{S}_{eff}}{{S}_{t eff}}$ | yᵢ |
|---|---|---|---|
| 1 | 0.7684 | 0.8663 | 0.6657 |
| 2 | 0.7190 | 0.9829 | 0.7067 |
| 3 | 0.7509 | 0.8634 | 0.6484 |
| 4 | 0.7409 | 0.9886 | 0.7325 |
| 5 | 0.6812 | 0.9826 | 0.6693 |
| 6 | 0.7413 | 0.8663 | 0.6422 |
| 7 | 0.6920 | 0.9826 | 0.6799 |
| 8 | 0.7380 | 0.8707 | 0.6426 |
| 9 | 0.9454 | 0.5407 | 0.5111 |
| 10 | 0.6767 | 0.9687 | 0.6555 |
| 11 | 0.9574 | 0.5363 | 0.5134 |
| 12 | 0.6870 | 0.9687 | 0.6655 |
| 13 | 0.6516 | 0.9626 | 0.6272 |
| 14 | 0.9667 | 0.5292 | 0.5116 |
| 15 | 0.6631 | 0.9685 | 0.6423 |
| 16 | 0.9870 | 0.5312 | 0.5243 |

Through the equation in the step (5), the average placement efficiency Tᵢ under different initial times for pumping the proppant, the average placement efficiency Nᵢ under different numbers of the slugs of the pumped proppant, and the average placement efficiency Aᵢ under different average diameters of the proppant particles are respectively calculated, and results thereof are as follows:
T₁=0.6183, T₂=0.6210, T₃=0.6290, T₄=0.6412;
N₁=0.6247, N₂=0.6380, N₃=0.6202, N₄=0.6266;
A₁=0.6971, A₂=0.6476, A₃=0.6497, A₄=0.5151.

Based on the above calculation results, the maximum values among Tᵢ, Nᵢ and Aᵢ are respectively selected, namely T₄, N₂ and A₁. According to the number corresponding to the maximum value and Table 2, the optimized initial time t_{c} for pumping the proppant, number n of the slugs of the pumped proppant, and average diameter a of the proppant particles are selected, respectively t_{c}=0.5 T=1200 s, n=6, and a=1×10⁻⁴ m.

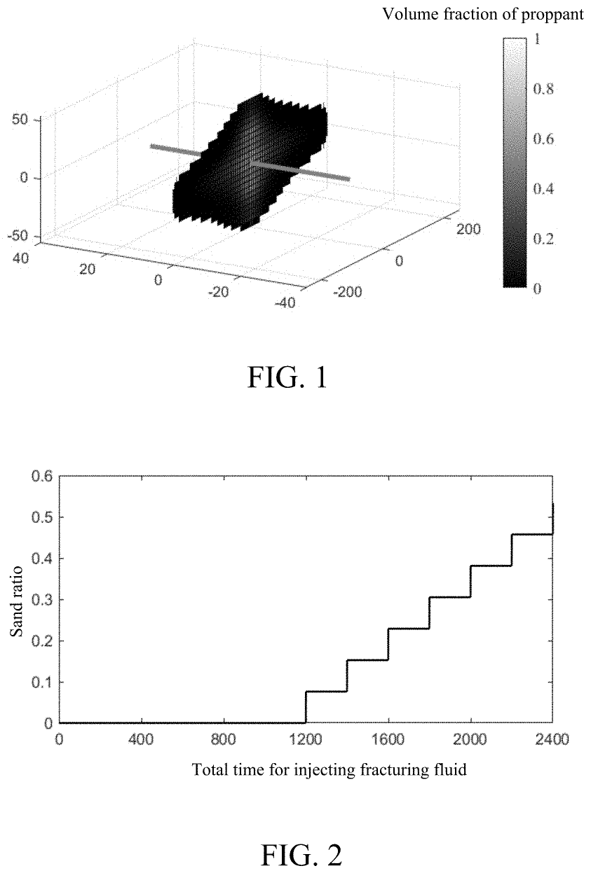

The optimized parameters of t_{c}, n and a are consistent with the 4^{th} set of parameters in Table 1 and Table 4, and the placement efficiency of the optimized design for proppant injection is yᵢ=0.7325. Compared with the calculation results of other sets, the optimized design has the highest placement efficiency, illustrating that the optimized parameters thereof are optimal. The fracture geometric size, the simulation result of proppant placement and the optimized sand ratio for proppant injection of the 4^{th} section of the tight gas well TL are shown in FIG. 1 and FIG. 2.

### Preferred Embodiment 2

The 1^{st} section of the tight oil well X2 is taken as an example, for further illustrating the method provided by the present invention.

According to the mathematical models constructed in the steps (1) and (2), the geometric size of the hydraulic fracture and the volumetric concentration distribution of the proppant after hydraulic fracturing are predicted. Based on the above models, according to the equation in the step (2), the pumped volume fraction φᵢₙ of the proppant is represented.

The geological and engineering parameters of the 1^{st} section of the tight oil well X2 are collected and listed in Table 5.

TABLE 5
Geological and engineering parameter table of 1^{st} section of tight oil well X2

| | | | |
|---|---|---|---|
| Young's modulus (E, in unit of MPa) | 32000 | Poisson's ratio (v) | 0.19 |
| Stress difference between pay zone | 0.7 | Thickness of pay zone (h, in unit | 40 |
| and interlayer (Δσ, in unit of MPa) | | of m) | |
| Fracturing fluid viscosity (μ, in unit of | 1 × 10⁻⁷ | Total pumped volume of | 0.02 |
| MPa · s) | | fracturing fluid (Qₒ, in unit of | |
| | | m³/s) | |
| Fracturing fluid density (ρ_{f}, in unit of | 1000 | Proppant density (ρₚ, in unit of | 2600 |
| kg/m³) | | kg/m³) | |
| Fracture toughness (K_{IC}, in unit of | 1 | Total time for injecting fracturing | 2000 |
| MPa · s^{0.5}) | | fluid (T, in unit of s) | |

For this section, 8 m³ quartz sand proppant is planned to be pumped; based on the 16 sets of initial time t_{c} for pumping the proppant, number n of the slugs of the pumped proppant, and average diameter a of the proppant particles, listed in Table 1, 16 sets of fracture geometric size and volumetric concentration distribution of the proppant are respectively calculated.

According to the obtained fracture geometric size and volumetric concentration distribution of the proppant, the placement efficiency of the proppant for 16 sets of parameters are respectively calculated through the equation in the step (4) and results thereof are listed in Table 6.

TABLE 6
Placement efficiency of proppant for 16 sets
of parameters in preferred embodiment 2

| Simulation number | $\frac{{Φ}_{eff}}{Φ}$ | $\frac{{S}_{eff}}{{S}_{t eff}}$ | yᵢ |
|---|---|---|---|
| 1 | 0.7310 | 0.9251 | 0.6762 |
| 2 | 0.8026 | 0.9773 | 0.7844 |
| 3 | 0.7651 | 0.9093 | 0.6958 |
| 4 | 0.8404 | 0.9773 | 0.8213 |
| 5 | 0.7294 | 0.9741 | 0.7106 |
| 6 | 0.7743 | 0.9093 | 0.7041 |
| 7 | 0.7390 | 0.9713 | 0.7178 |
| 8 | 0.8437 | 0.9093 | 0.7673 |
| 9 | 0.8151 | 0.7615 | 0.6207 |
| 10 | 0.7997 | 0.9660 | 0.7725 |
| 11 | 0.8287 | 0.7564 | 0.6268 |
| 12 | 0.8212 | 0.9717 | 0.7980 |
| 13 | 0.7326 | 0.9713 | 0.7116 |
| 14 | 0.8371 | 0.7620 | 0.6379 |
| 15 | 0.7558 | 0.9603 | 0.7259 |
| 16 | 0.8553 | 0.7620 | 0.6518 |

Through the equation in the step (5), the average placement efficiency Tᵢ under different initial times for pumping the proppant, the average placement efficiency Nᵢ under different numbers of the slugs of the pumped proppant, and the average placement efficiency Aᵢ under different average diameters of the proppant particles are respectively calculated, and results thereof are as follows:
T₁=0.6798, T₂=0.6916, T₃=0.7247, T₄=0.7596;
N₁=0.7102, N₂=0.7153, N₃=0.7193, N₄=0.7109;
A₁=0.7585, A₂=0.7520, A₃=0.7108, A₄=0.6343.

Based on the above calculation results, the maximum values among Tᵢ, Nᵢ and Aᵢ are respectively selected, namely T₄, N₃ and A₁. According to the number corresponding to the maximum value and Table 2, the optimized initial time t_{c} for pumping the proppant, number n of the slugs of the pumped proppant, and average diameter a of the proppant particles are selected, respectively t_{c}=0.5 T=1000 s, n=9, and a=1×10⁻⁴ m.

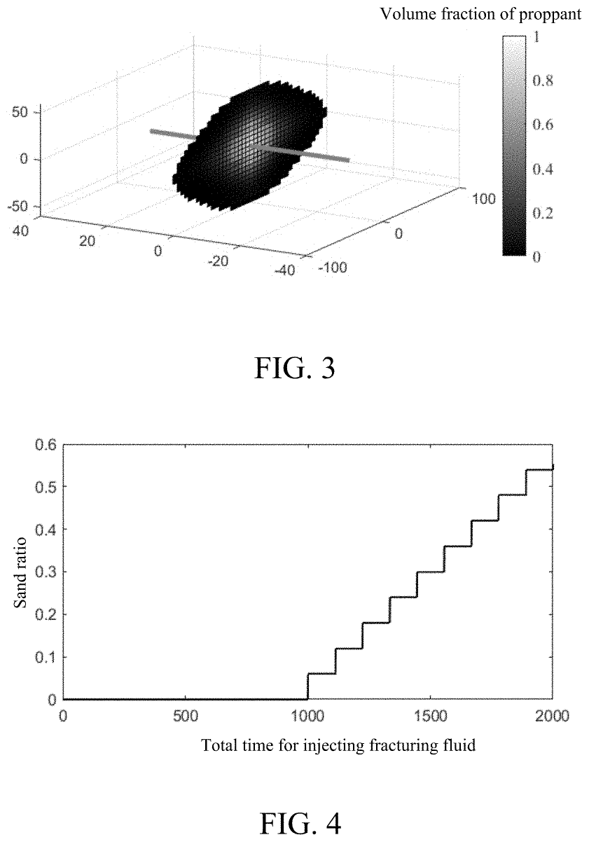

Through substituting the optimized parameters of t_{c}, n and a into the models constructed in the steps (1) and (2), the corresponding fracture geometric size and volumetric concentration distribution of the proppant are obtained; through the step (4), the placement efficiency yᵢ of the proppant after fracturing is calculated, yᵢ=0.8317. Compared with the results of 16 sets in Table 6, the placement efficiency yᵢ of 0.8317 is maximum. The optimized design has the highest placement efficiency, illustrating that the optimized parameters thereof are optimal. The fracture geometric size, the simulation result of proppant placement and the optimized sand ratio for proppant injection of the 1^{st} section of the tight oil well X2 are shown in FIG. 3 and FIG. 4.

The present invention provides an optimization method for a proppant injection program, which is able to place the proppant particles of a predetermined total volume within an oil & gas pay zone as far as possible under specific geological and engineering conditions. The optimized parameters obtained through the method provided by the present invention can increase both the ratios of volume and cover area of the proppant placed in the pay zone, so that the problem of one-sidedness in the conventional design method is solved. The initial time t_{c} for pumping the proppant, the number n of the slugs of the pumped proppant and the average diameter a of the proppant particles are adopted to represent the design for pumping the proppant. With the orthogonal analyses, the optimization method has objectivity and practicability. The present invention presents a fracturing numerical model, which is fully fluid-solid coupled with considering the transport of the proppants, and the fracturing model is able to quantitatively evaluate the concentration distribution of the proppant in the hydraulic fracture. By utilizing the presented model, the optimized result of the present invention has objectivity with eliminating the interference of the subjective evaluation.

What is claimed is:

1. An optimization method for high-efficiently placing proppants in a hydraulic fracturing treatment, comprising steps of:
(1) constructing a rock deformation governing equation during a fracturing process; constructing a material balance equation of flowing of fracturing fluid and transport of the proppant; coupling the equations and constructing a fracture propagation model, for solving a geometric size of a hydraulic fracture and a volumetric concentration distribution of the proppant;
(2) constructing a model for representing a pumped volume fraction of the proppant;
(3) according to geological and engineering parameters of a target area,
determining a total pumped volume of the proppant; determining d different initial times for pumping the proppant, d different numbers of slugs of the pumped proppant, and d different average diameters of proppant particles; according to a L_{d×d} table of orthogonal experimental design, obtaining d×d sets of parameters; substituting the d×d sets of parameters respectively into the models constructed in the steps (1) and (2), and obtaining corresponding fracture geometric size and volumetric concentration distribution of the proppant;
(4) according to the fracture geometric size and the volumetric concentration distribution of the proppant, which are obtained in the step (3), calculating a placement efficiency of the proppant for each set of parameters;
(5) according to the placement efficiency of the proppant, which is obtained in the step (4), respectively calculating an average placement efficiency Tᵢ under different initial times for pumping the proppant, an average placement efficiency Nᵢ under different numbers of the slugs of the pumped proppant, and an average placement efficiency Aᵢ under different average diameters of the proppant particles, 1=1, 2, . . . , d;
(6) according to results obtained in the step (5), respectively selecting a maximum value among Tᵢ, Nᵢ and Aᵢ; according to the maximum value, selecting the corresponding initial time for pumping the proppant, number of the slugs of the pumped proppant and average diameter of the proppant particles, as optimized parameters;
(7) substituting the optimized parameters obtained in the step (6) into the models constructed in the steps (1) and (2), and obtaining the corresponding fracture geometric size and volumetric concentration distribution of the proppant; calculating the placement efficiency of the proppant as step (4), and verifying whether the placement efficiency is maximum, which means the optimized parameters obtained in the step (6) are optimal.

2. The optimization method, as recited in claim 1, wherein: the rock deformation governing equation during the fracturing process in the step (1) is:
p(x′,y′)=σ(y′)+∫ₛ(x′−x,y′−y)w(x,y)dxdy;
in the equation, x and y are space coordinates; p is a net pressure value in the fracture; σ is a value of a minimum principal stress of formation; w is a width of the hydraulic fracture; C is a kernel function; and S is a fracture area; wherein:
the kernel function C is:
$$C ( x , y ) = - \frac{E}{8 π ( 1 - {ν}^{2} )} \frac{1}{{( {x}^{2} + {y}^{2} )}^{3 / 2}} ;$$
in the equation, v is a Poisson's ratio of reservoir rocks, and E is a Young's modulus of the reservoir rocks;
the material balance equation of flowing of the fracturing fluid and transport of the proppant is:
$$\{ \begin{matrix}\frac{\partial w}{\partial t} + ∇ \cdot {q}_{s} = {Q}_{0} δ ( x , y ) \\ \frac{\partial w φ}{\partial t} + ∇ \cdot {q}_{p} = {Q}_{0} {φ}_{in} δ ( x , y )\end{matrix} ;$$
in the equation, qₛ is a flowing rate of the fracturing fluid; qₚ is a transport rate of the proppant; Q₀ is a pumped volume of the fracturing fluid; φᵢₙ is the pumped volume fraction of the proppant; φ is a volume fraction of the proppant in the fracture; and t is time; wherein:
$$\{ \begin{matrix}{q}_{s} = \frac{{w}^{3}}{12 μ} {Q}_{s} ( φ ) ∇ p \\ {q}_{p} = B ( φ ) ( {Q}_{p} ( φ ) {q}_{s} - \frac{{a}^{2} w}{12 μ} {gG}_{p} ( φ ) )\end{matrix} ;$$
in the equation, Qₛ is a dimensionless equation representing rheology of the fracturing fluid; μ is a viscosity of the fracturing fluid; B is a blocking equation of the proppant; Qₚ is a dimensionless equation representing a transport mechanism of the proppant; a is the average diameter of the proppant particles; g is a gravitational acceleration; and Gₚ is a dimensionless equation representing a settlement mechanism of the proppant;
$$\{ \begin{matrix}{Q}_{s} ( φ ) = {( 1 - φ )}^{2} \\ {Q}_{p} ( φ ) = 1.2 {φ ( 1 - φ )}^{0.1} \\ {G}_{p} ( φ ) = 2.3 {φ ( 1 - φ )}^{2}\end{matrix} ; \\ B ( φ ) = H ( \frac{w}{a} - 4 ) + ( \frac{w}{a} - 3 ) H ( 4 - \frac{w}{a} ) H ( \frac{w}{a} - 3 ) ;$$
in the equation, H is a unit step function;
a boundary condition of a fracture tip is:
$${lim}_{r \to 0} w = \sqrt{\frac{32}{π}} \frac{{K}_{1 C} ( 1 - {ν}^{2} )}{E} {r}^{1 / 2} ;$$
in the equation, K_{IC} is a fracture toughness, and r is a distance away from the fracture tip.

3. The optimization method, as recited in claim 2, wherein: the model constructed in the step (2) is:
$$\{ \begin{matrix}Δ {t}_{p} = ( T - {t}_{c} ) / n \\ Δφ = 2 Φ / [ ( n + 1 ) ( T - {t}_{c} ) ] \\ {φ}_{in} = ⌊ ( t - {t}_{c} ) / {Δt}_{p} + 1 ⌋ Δφ / {Q}_{0} / 0.64\end{matrix} ;$$
in the equation, Δtₚ is a duration time of each slug of the proppant; T is a total time for injecting the fracturing fluid; t_{c} is the initial time for pumping the proppant; n is the number of the slugs of the pumped proppant; Δφ is an increment of the volume fraction of the proppant between two neighboring slugs; Φ is the total pumped volume of the proppant; φᵢₙ is the pumped volume fraction of the proppant; t is time; and Q₀ is the pumped volume of the fracturing fluid.

4. The optimization method, as recited in claim 3, wherein: the placement efficiency yᵢ of the proppant in the step (4) is calculated as follows:
$${y}_{i} = \frac{{Φ}_{eff}}{Φ} \frac{{S}_{eff}}{{S}_{teff}} , i = 1 , 2 , 3 … m ;$$
in the equation, Φ_{eff} is a volume of the proppant placed in an oil & gas pay zone after fracturing; S_{eff} is an area of the proppant placed in the oil & gas pay zone after fracturing; S_{teff} is a total area of the oil & gas pay zone covered by the hydraulic fracture after fracturing; Φ is the total pumped volume of the proppant; m is an amount of parameter sets and equals to d×d.

5. The optimization method, as recited in claim 4, further comprising steps of: comparing the placement efficiency of the proppant, which is obtained in the step (7), with the placement efficiencies of m sets which are obtained in the step (4), wherein: if the placement efficiency obtained in the step (7) is maximum, the optimized parameters obtained in the step (6) are considered as optimal results.
